(19) United States
(12) Patent Application Publication
(10) Pub. No.: US 2012/0062082 A1
(43) Pub. Date: Mar. 15, 2012

(54) Housing structure of electronic device and manufacturing method thereof

(75) Inventor: Shu-Chen Lin, Taoyuan City (TW)

(73) Assignee: Quanta Computer Inc., Tao Yuan Shien (TW)

(21) Appl. No.: 13/064,083

(22) Filed: Mar. 4, 2011

(30) Foreign Application Priority Data
Sep. 15, 2010 (TW) 099131260

(51) Int. Cl. H05K 5/02; H05K 13/00

(52) U.S. Cl. 312/223.1; 216/37

(57) ABSTRACT

A housing structure of electronic device and a manufacturing method thereof are provided. The housing structure of electronic device comprises a metal member and a plastic member. A surface of the metal member is formed with a plurality of micro anchored apertures. Each micro anchored aperture has an irregular inner wall. The plastic member is integrated on the surface of the metal member, wherein the plastic member extends in the micro anchored apertures and fully abutted and adhered on the irregular inner walls.

### RELATED APPLICATIONS

This application claims priorities to Taiwan Application Serial Number 099131260, filed on Sep. 15, 2010, which is herein incorporated by reference.

### BACKGROUND

1. Technical Field

The present invention relates to a housing structure of electronic device and a manufacturing method thereof, more particular to a housing structure of electronic device and a manufacturing method thereof for combing a metal member and a plastic member.

2. Description of Related Art

With the development of technology, an electronic device, e.g. a notebook computer, cell phone or personal digital assistant (PDA) is widely used. At present, in an electronic device, the combination methods of metal member and plastic member together mainly are structural screwing methods, plastic structure molten methods, adhesive applying methods and methods of embedding metal member for injection molding.

When the thickness of metal housing of an electronic device is thinned to a certain level, there is no sufficient room for adopting mechanisms of screwing, buckling and molten soldering, and the metal member and the plastic member may be separated due to insufficient combination strength, and the product quality is therefore sacrificed.

### SUMMARY

The present invention discloses a housing structure of electronic device and a manufacturing method thereof, that enables a plastic member to be integrally formed on a metal member after being processed with treatments, and a strong combination force can be generated between the two members without needs of applying adhering or surfactant agents.

The manufacturing method of housing structure of electronic device according to the present invention comprises the steps of providing a metal member, a surface thereof is processed with an anodic oxidization treatment to form an oxidized film on the surface of the metal member, the oxidized film has plural nano-class apertures, each nano-class aperture has a straight and flat inner wall; the nano-class apertures are processed with an etching treatment for expanding the size of each nano-class aperture so as to change into a micro anchored aperture, and each micro anchored aperture has an inner wall which is with uneven cavities and protrusions thereon and is in an uneven or irregular shape; and a molten plastic material is formed on the surface of the metal member with an injection molding manner, so the plastic material is filled in the micro anchored apertures and fully abutted and adhered on the inner walls of the micro anchored apertures.

In one embodiment according to the present invention, the micro anchored apertures are separated apart through partition barriers of the oxidized film, and after performing an etching treatment to the partition barriers, the partition barriers are expanded or broken so as to be in communication with each other.

In one embodiment according to the present invention, in the step of processing an anodic oxidization treatment to the metal member further comprises providing an acid solution to be in contact with and act on the surface of the metal member for processing the anodic oxidization treatment.

In another embodiment according to the present invention, in the step of processing an etching treatment to the nano-class apertures, further comprises providing a chemical solution to be in contact with and act on the surface of the metal member having the nano-class apertures, such that the chemical solution permeates and etches the nano-class apertures, and the depths and diameters of the nano-class apertures are expanded, and the surface of each inner wall of the nano-class aperture is roughen for forming an inner wall with uneven cavities and protrusions.

In one another embodiment according to the present invention, in the step of providing a metal member, further comprises forming a notch on the metal member, such that micro anchored apertures can be formed at certain areas. And in the step of processing the anodic oxidization treatment to the surface of the metal member, further comprises processing an the anodic oxidization treatment to the inner surface of the notch, then processing an etching treatment to the nano-class apertures formed in the notch.

The housing structure of electronic device according to the present invention comprises a metal member and a plastic member. A surface of the metal member is formed with a plurality of micro anchored apertures thereon. Each micro anchored aperture has an inner wall with uneven cavities and protrusions. The plastic member is integrated on the surface of the metal member by an injection molding manner, wherein the plastic member extends in the micro anchored apertures and fully abutted and adhered on the uneven cavities and the protrusions of the inner walls of the micro anchored apertures.

In one embodiment according to the present invention, the material of the metal member is magnesium, aluminum, titanium or an alloy thereof.

In another embodiment according to the present invention, the plastic member can be a hollow convex post, a solid convex post, a convex rib, a hook, or a flange.

In one another embodiment according to the present invention, the metal member is provided with a notch, and the micro anchored apertures are formed on the inner surface of the notch.

As such, with the uneven inner walls of the micro anchored apertures, the plastic material can be filled in the micro anchored apertures and completely abutted and adhered on the inner walls of the micro anchored apertures according to the shapes of the inner walls of the micro anchored apertures, after the plastic material is cooled and formed as a plastic member, the plastic member is firmed held and retained in the micro anchored apertures, such that the part of the plastic member corresponding to the shapes of the inner walls of the micro anchored apertures can not be removed from the micro anchored apertures, the tension and the combination force between the plastic member and the metal member are greatly increased, and the possibility of the plastic member releasing from the metal member is reduced.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a flow chart showing the manufacturing method of a housing structure of electronic device according to one embodiment of the present invention.

FIG. 2A is a schematic view showing the metal member of the housing structure of electronic device being processed with the step (101) of FIG. 1 according to the present invention.

FIG. 2B is a schematic view showing the metal member of the housing structure of electronic device after being processed with the step (103) of FIG. 1 according to the present invention.

FIG. 2C is a schematic view showing the metal member of the housing structure of electronic device after being processed with the step (105) of FIG. 1 according to the present invention.

FIG. 2D is a schematic view showing the metal member of the housing structure of electronic device after being processed with the step (107) of FIG. 1 according to the present invention.

FIG. 3 is a schematic side view showing the metal member of the housing structure of electronic device being formed with a notch, according to the present invention.

FIG. 4 is a schematic view showing the metal member of the housing structure of electronic device according to one embodiment of the present invention.

FIG. 5A is a schematic view showing one alternative of the metal member of the housing structure of electronic device according to the present invention.

FIG. 5B is a cross sectional view taken along line 5B-5B of FIG. 5A.

FIG. 6 is a schematic view showing one another alternative of the metal member of the housing structure of electronic device according to the present invention.

### DESCRIPTION OF THE PREFERRED EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

In view of the conventional embedded injection molding process for manufacturing a housing structure of electronic device, a plastic member is formed on an oxidized film of a metal member through an injection molding manner, thus the combination force between the mentioned two members is not sufficient, so the plastic member is very likely to release from or break on the metal member. The present invention provides an improved manufacturing method, in which before a plastic member is formed on a surface of a metal member with an injection molding manner, the metal member is processed with an anodic oxidization treatment for forming aligned nano-class apertures, and the nano-class apertures are expanded after being etched, so when a plastic material is filled in the expanded apertures, an effect acting like an anchor is generated, so an object of preventing the plastic member from releasing from the metal member is achieved.

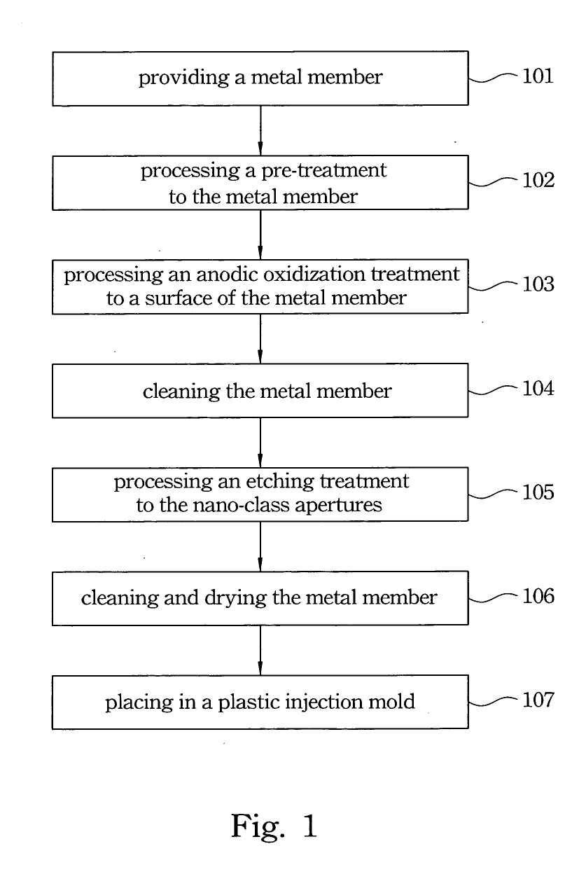

Referring to FIG. 1, which is a flow chart showing the manufacturing method of a housing structure of electronic device according to one embodiment of the present invention. In this embodiment according to the present invention, the manufacturing method of a housing structure of electronic device comprises the following steps:

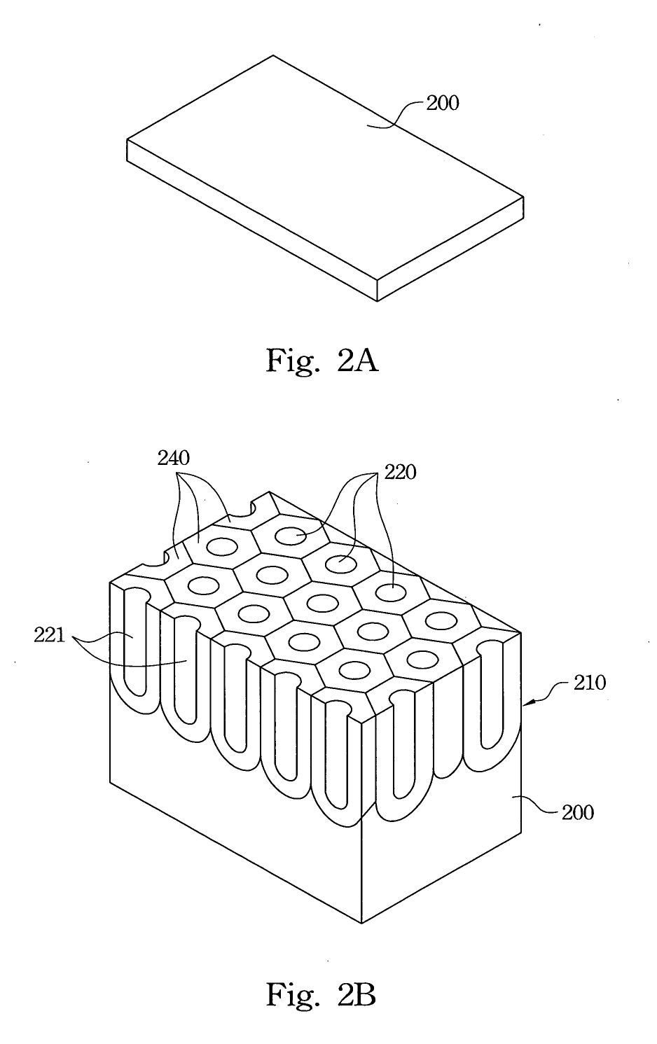

Step (101): providing a metal member 200 (referring to FIG. 2A, which is a schematic view showing the metal member 200 of the housing structure of electronic device being processed with the step (101) of FIG. 1 according to the present invention).

In the step of providing the metal member 200, the metal member 200 of the housing structure of electronic device can be formed through a metal processing means, such as casting, extruding or forging. The material of the metal member 200 can be aluminum, titanium or an alloy of the aluminum and titanium.

Step (102): processing a pre-treatment to the metal member 200.

In this step, more detailed steps are disclosed as followings: (1) the metal member 200 being immersed in a Pyruvic acid (CH3COCOOH) solution; (2) processing a first ultrasonic cleaning with purified water to the metal member 200 immerged in the Pyruvic acid solution; (3) immersing the metal member 200 after being cleaned by ultrasonic in a Potassium Hydroxide (KOH) solution; (4) processing an electrolytic polishing treatment to the metal member 200; and (5) processing a second ultrasonic cleaning to the metal member 200.

Step (103): processing an anodic oxidization treatment to a surface of the metal member 200 (referring to FIG. 2B, which is a schematic view showing the metal member 200 of the housing structure of electronic device after being processed with the step (103) of FIG. 1 according to the present invention).

In this step, when an acid solution is utilized to process the anodic oxidation treatment to the surface of the metal member 200, an oxidized film 210 is formed on the surface of the metal member 200. The oxidized film 210 fully covers the surface of the metal member 200 and is uniformly arranged to an aperture array format; because the diameter (e.g. 40-50 nm) of the arranged aperture array is qualified to be categorized as a nano meter class, the apertures at this stage are defined as nano-class apertures 220. Moreover, each nano-class aperture 220 has a flat and straight inner wall 221. What shall be addressed is that the nano-class apertures 220 do not penetrate the oxidized film 210.

Step (104): cleaning the metal member 200.

In this step, after the metal member 200 is formed with the nano-class apertures 220, the metal member 200 including the nano-class apertures 220 is processed with an ultrasonic cleaning operation with purified water.

Step (105): processing an etching treatment to the nano-class apertures 220 of the metal member 200 (Referring to FIG. 2B and FIG. 2C, wherein FIG. 2C is a schematic view showing the metal member 200 of the housing structure of electronic device after being processed with the step (105) of FIG. 1 according to the present invention).

After repeatedly trying and doing experiments, the applicant of the present invention has discovered that when the metal member 200 being formed with the nano-class apertures 220 through the step (103) then directly being placed in a plastic injection mold, because the depth and roughness which the plastic material being filled is the nano-class apertures 220 are not sufficient, the tension and combination force are apparently not enough, and the plastic material may come off or break from the metal member 200.

Therefore, in the step (105), an etching treatment is utilized to process to the nano-class apertures 220 of the metal member 200.

In this step, a chemical solution is provided to be in contact with and act on the surface of the metal member 200 having the nano-class apertures 220, so the chemical solution can permeate and etch the nano-class apertures 220 for enlarging the size of each nano-class aperture 220. The types and details of the chemical solution will be disclosed hereinafter. Because the diameter of the nano-class aperture 220 is expanded to a size defined as a micro meter class, the nano-class aperture 220 after being etched is named as a micro anchored aperture 230.

Step (106): cleaning and drying the metal member 200.

In this step, after the metal member 200 is formed with the micro anchored apertures 230, the metal member 200 is processed with an electrolytic polishing treatment and an ultrasonic cleaning operation is processed to the metal member 200 including the micro anchored apertures 230 through purified water, then the metal member 200 is completely dried.

Step (107): placing in a plastic injection mold (referring to FIG. 2D, which is a schematic view showing the metal member 200 of the housing structure of electronic device after being processed with the step (107) of FIG. 1 according to the present invention).

In this step, when the metal member 200 is placed in the plastic injection mold, a molten plastic material is provided to integrate on a surface of the metal member 200 with an injection molding manner, and when the plastic material on the surface of the metal member 200 is filled in the micro anchored apertures 230, the plastic material is fully abutted and adhered on inner walls 231 of the micro anchored apertures 230 so as to form a plastic member 400, thus a housing structure of electronic device in which the plastic member 400 being integrally formed with the metal member 200 is obtained.

Referring to FIG. 2B, in one embodiment according to the present invention, when the surface of the metal member 200 is processed with the anodic oxidization treatment in the step (103), an acid solution, such as Oxalic acid (C2H2O4) or sulfuric acid (H2SO4), is provided for being in contact with and acting on the surface of the metal member 200, so as an oxidized film 210 is formed on the surface of the metal member 200.

Moreover, when the whole surface of the metal member 200 is processed with the anodic oxidization treatment, the metal member 200 is placed in an electrolytic cell containing the mentioned acid solution and an anode electrode. The electrolytic cell is regulated to a certain stable temperature, then the anodic oxidization treatment can be processed; after the treatment is finished and the metal member 200 is removed, residual anodic oxidization solution on the surface of the metal member 200 can be rinsed by deionized water.

Referring to FIG. 2B and FIG. 2C, in another embodiment according to the present invention, when the step (105) is processed, a chemical solution such as phosphoric acid or sulfuric acid is provided for immersing and acting on the surface of the metal member 200 having the nano-class apertures 220, so the chemical solution etches the nano-class apertures 200, and the size of each nano-class aperture 220 is enlarged and the inner wall 221 of each nano-class aperture 220 is roughen.

In details, the action of enlarging the size of nano-class aperture 220 comprises deepening the depth of each nano-class aperture 220 and expanding the diameter of each nano-class aperture 220, and the depth and diameter of each nano-class aperture 220 are different. Moreover, through etching by the chemical solution, each inner wall 231 of the micro anchored apertures 230 is formed in an irregular dendritic shape, and a rough surface with uneven cavities or protrusions is formed thereon. In one preferred embodiment according to the present, the diameters of the micro anchored apertures 230 are in a range below 5-6 micrometer.

In the process of etching treatment, several factors shall be addressed, such as the temperature and concentration of the etching acid solution (e.g. 5% in weight and at 20 Celsius degree). The higher the temperature, the faster the etching speed; and the higher concentration of the chemical solution (i.e. the etching solution), the faster the etching speed; a strong acid solution or a strong alkaline solution can both be served to achieve the etching effect.

The micro anchored apertures 230 are separated apart by partition barriers 240 of the oxidized film 210. Through controlling parameters of anodic treatment, particles of the partition barriers 240 of the oxidized film 210 can be separated easily and the sizes thereof can be the same, after the etching treatment, the particles of the partition barriers 240 can be partially damaged, broken or expanded, so as the micro anchored apertures 230 are in communication with each other through the oxidized film 210 (as shown in FIG. 2C). Accordingly, when the step (107) is processed, and the plastic material is filled in the micro anchored apertures 230, a tension force acting like an anchor to secure the plastic member 400 and the metal member 200 is generated, so the combination force between the plastic member 400 and the metal member 200 is greatly enhanced.

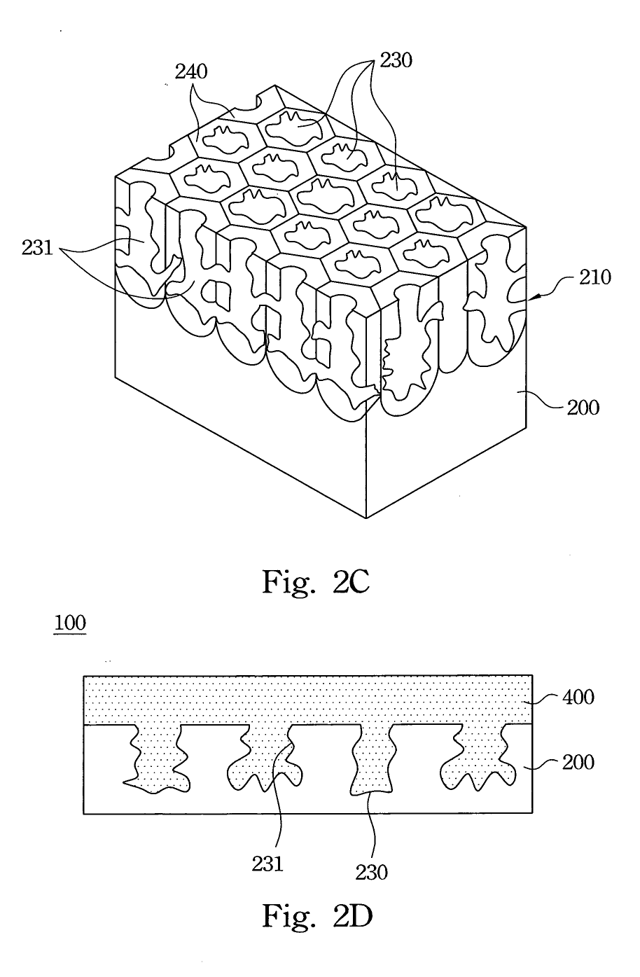

Referring to FIG. 3, according to the present invention, which is a schematic view showing the metal member 200 of the housing structure of electronic device being formed with a notch 250. In one another embodiment according to the present invention, when only a part of the surface of the metal member 200 is desired to be formed with the micro anchored apertures 230, in the step (101) of forming the metal member 200 through a metal processing manner such as casting, extruding or forging, a notch 250 can be formed on the partial surface of the metal member 200 by pressing.

When the metal member 200 having the notch 250 is processed with the step (103), an anodic oxidization treatment is firstly processed in the notch 250 only, so an oxidized film 210 and the nano-class apertures 220 (referring to FIG. 2B) are formed in the inner surface of the notch 250 only.

When the metal member 200 having the notch 250 is processed with the step (105), the mentioned chemical solution can be poured in the notch 250 only, such that the mentioned chemical solution is only in contact with the inner surface of the notch 250, and an etching treatment is processed to the nano-class apertures 220 on the inner surface of the notch 250, the micro anchored apertures 230 are therefore formed (referring to FIG. 2C and FIG. 2D). Moreover, the notch 250 enables the chemical solution to be gathered and be limited in the designed notch 250; because the step (105) is processed in the aligned notch, the formed micro anchored apertures 230 are also aligned. As such, the cost for forming micro anchored apertures 230 on a larger area is saved.

Referring to FIG. 2D, the present invention discloses a housing structure of electronic device 100. The housing structure of electronic device 100 comprises a metal member 200 and a plastic member 400. A surface of the metal member 200 is formed with a plurality of micro anchored apertures 230. Each micro anchored aperture 230 has an inner wall 231 with uneven cavities and protrusions. The plastic member 400 is integrated on the surface of the metal member 200 with an injection molding manner, wherein the plastic member 400 extends in the micro anchored apertures 230 and fully abutted and adhered on the inner walls 231 of the micro anchored apertures 230.

In one embodiment according to the present invention, the metal member 200 can be in a plate shape. The appearance of the plastic member 400 can be varied as a hollow convex post, a solid convex post, a convex rib, a hook or a flange.

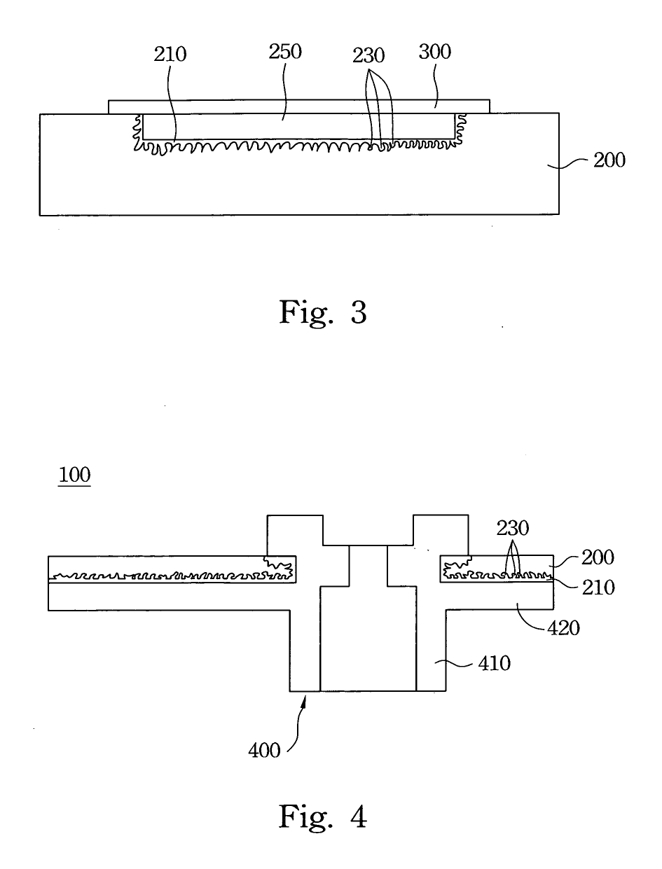

Referring to FIG. 4, which is a schematic view showing the metal member of the housing structure of electronic device according to one embodiment of the present invention. In an alternative of the plastic member 400, the metal member 200 has an opening. The plastic member 400 comprises a hollow convex post 410 and an extension part 420, the hollow convex post 410 penetrates the opening and is combined with the metal member 200, and the extension part 420 and the hollow convex post 410 are integrally formed and adhered on one surface of the metal member 200.

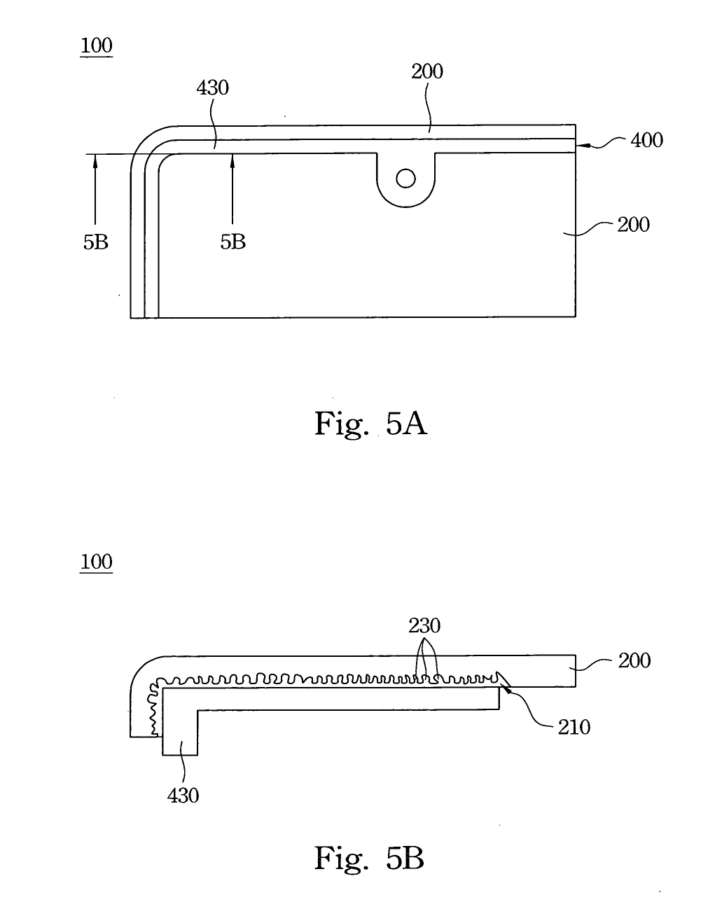

Referring to FIG. 5A and FIG. 5B; wherein FIG. 5A is a schematic view showing one alternative of the metal member of the housing structure of electronic device according to the present invention; FIG. 5B is a cross sectional view taken along line 5B-5B of FIG. 5A. In another alternative of the plastic member 400, the plastic member 400 is a convex rib 430 surrounding the edge of the metal member 200 and combined on a surface of the metal member 200.

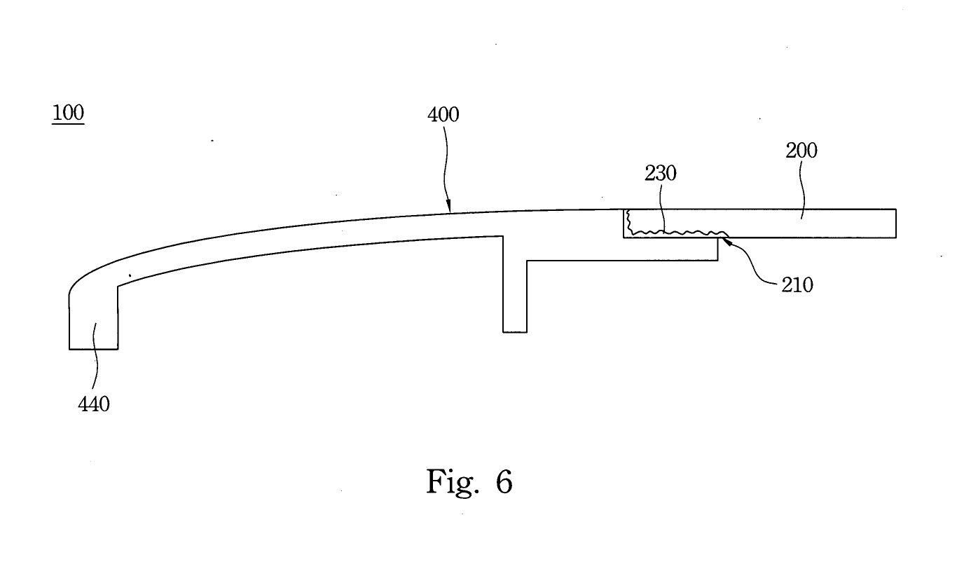

Referring to FIG. 6, which is a schematic view showing one another alternative of the metal member 200 of the housing structure of electronic device 100 according to the present invention. In one another alternative of the plastic member 400, the plastic member 400 is a flange 440 formed at the edge of the metal member 200 and combined on a surface of the metal member 200.

As mentioned above, with the uneven inner walls of the micro anchored apertures, the plastic material can be filled in the micro anchored apertures and completely abutted and adhered on the inner walls of the micro anchored apertures according to the shapes of the inner walls of the micro anchored apertures, after the plastic material is cooled and formed as a plastic member, the plastic member is firmed held and retained in the micro anchored apertures, such that the part of the plastic member corresponding to the shapes of the inner walls of the micro anchored apertures can not be removed from the micro anchored apertures, the tension and the combination force between the plastic member and the metal member are greatly increased, and the possibility of the plastic member releasing from the metal member is reduced.

Although the present invention has been described with reference to the preferred embodiments thereof, it is apparent to those skilled in the art that a variety of modifications and changes may be made without departing from the scope of the present invention which is intended to be defined by the appended claims.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A manufacturing method of housing structure of electronic device, comprising:
providing a metal member;
processing an anodic oxidization treatment to the metal member to form an oxidized film on a surface of the metal member, wherein the oxidized film has plural apertures, each of the apertures has an inner wall;
processing an etching treatment to the apertures for expanding the size of each aperture so as to form a micro anchored aperture, wherein the inner walls of the micro anchored apertures are formed with uneven cavities and protrusions thereon; and
providing a molten plastic material to integrate on the surface of the metal member with an injection molding manner, wherein the plastic material is filled in the micro anchored apertures and fully abutted and adhered on inner walls of the micro anchored apertures.

2. The manufacturing method of housing structure of electronic device according to claim 1, wherein the diameter of each aperture is between 40-50 nanometer; the diameter of each micro anchored aperture is below 5 micrometer.

3. The manufacturing method of housing structure of electronic device according to claim 1, wherein the micro anchored apertures are separated apart through partition barriers of the oxidized film, and after performing the etching treatment to the partition barriers, the partition barriers are expanded or broken so as to be in communication with each other.

4. The manufacturing method of housing structure of electronic device according to claim 1, wherein the step of processing the anodic oxidization treatment to the metal member further comprises:
providing an acid solution to be in contact with and acting on the surface of the metal member for processing the anodic oxidization treatment.

5. The manufacturing method of housing structure of electronic device according to claim 4, wherein the step of processing the etching treatment to the apertures further comprises:
providing a chemical solution to be in contact with and acting on the surface of the metal member having the apertures, such that the chemical solution permeates and etches the apertures, and the depths and diameters of the apertures are expanded, and the surface of each inner wall of the aperture is roughen.

6. The manufacturing method of housing structure of electronic device according to claim 5, wherein the step of providing the metal member further comprises:
forming a notch on the metal member.

7. The manufacturing method of housing structure of electronic device according to claim 6, wherein the step of processing the anodic oxidization treatment to the surface of the metal member further comprises:
processing an anodic oxidization treatment to the inner surface of the notch.

8. The manufacturing method of housing structure of electronic device according to claim 7, wherein the step of processing the etching treatment to the apertures further comprises:
processing an etching treatment to the apertures formed on the inner surface of the notch.

9. A housing structure of electronic device, comprising:
a metal member having a surface thereof formed with a plurality of micro anchored apertures thereon, wherein each of the micro anchored apertures has an inner wall with uneven cavities and protrusions; and
a plastic member integrated on the surface of the metal member by an injection molding manner, wherein the plastic member extends in the micro anchored apertures and fully abutted and adhered on the uneven cavities and the protrusions of the inner walls.

10. The housing structure of electronic device according to claim 9, wherein the material of the metal member is selected from a group consisted of aluminum alloy and titanium alloy.

11. The housing structure of electronic device according to claim 9, wherein the plastic member is a hollow convex post, a solid convex post, a convex rib, a hook or a flange.

12. The housing structure of electronic device according to claim 9, wherein the metal member is provided with a notch, and the micro anchored apertures are formed on the inner surface of the notch.
